(19) United States
(12) Patent Application Publication
(10) Pub. No.: US 2014/0021458 A1
(43) Pub. Date: Jan. 23, 2014

(54) ORGANIC ELECTRO-LUMINESCENCE DISPLAY PANEL AND METHOD OF MANUFACTURING THE SAME

(71) Applicant: TOPPAN PRINTING CO., LTD., Tokyo (JP)

(72) Inventors: Hiroshi TADA, Tokyo (JP); Ryo SHODA, Tokyo (JP)

(73) Assignee: TOPPAN PRINTING CO., LTD., Tokyo (JP)

(21) Appl. No.: 14/036,986

(22) Filed: Sep. 25, 2013

Related U.S. Application Data
(63) Continuation of application No. PCT/JP2012/057557, filed on Mar. 23, 2012.

(30) Foreign Application Priority Data
Mar. 25, 2011 (JP) 2011-068601

(51) Int. Cl. H01L 51/50

(52) U.S. Cl. CPC H01L 51/5012
USPC 257/40; 438/34

(57) ABSTRACT

In an organic electro-luminescence display panel, an organic EL element is formed on a substrate. In the organic EL element, a first electrode formed on the substrate and has an electrode portion and a connection portion. A planarizing layer is formed around edges of the electrode portion. The planarizing layer planarizes a boundary with the first electrode. A partitioning wall has an aperture at an inside thereof. The partitioning wall is formed to be separated from the edges of the electrode portion toward the planarizing layer. A luminescent medium layer includes at least an organic luminescent layer and formed, in the aperture of the partitioning wall, on the first electrode and the planarizing layer. A second electrode is formed to be separated by the luminescent medium layer from the first electrode.

### TECHNICAL FIELD

The present invention relates to organic electro-luminescence display panels using electro-luminescence, referred to as EL hereinafter, and methods of manufacturing the organic electro-luminescence display panels.

### BACKGROUND ART

Organic electro-luminescence elements, referred to as organic EL elements, are comprised of an organic luminescent layer made from an organic luminescent material sandwiched by two opposing electrodes. When energized, the organic luminescent layers emit light.

In order to efficiently manufacture a reliable organic electro-luminescence element, the thickness of the organic layer is important. In order to manufacture a color display using an organic electro-luminescence element, high-definition patterning is required.

FIG. 9 schematically illustrates a normal organic electro-luminescence display panel. One pixel 101 of an organic display panel 100 is comprised of sub-pixels 102 having three primary colors of red (R), green (G), and blue (B). Each sub-pixel 102 is comprised of an organic EL element emitting a corresponding color. If each sub-pixel is an active-drive element, it also comprised of a thin-film transistor, referred to as a TFT hereinafter.

Usually, as a substrate for displays, a substrate, in which a patterned insulator, such as photosensitive polyimide, is formed as a partitioning wall such that sub-pixels are partitioned, is used. In this case, the partitioning-wall pattern is formed to cover edges of a transparent electrode as an anode, defining sub-pixel regions.

A hole injection layer for injection of hole carriers is formed on the transparent electrodes and the partitioning-wall pattern. In order to form a hole injection layer, there are two kinds of dry-deposition methods and wet-deposition methods. In the wet-deposition methods, a polythiophene derivative dispersed in water is usually used. Water-based ink used in the wet-deposition methods is open to influence of a base, resulting in a difficulty uniformly coating it. In contrast, vapor deposition as an example of the dry-deposition methods easily enables uniform full-face coating on a substrate.

There are also two kinds of dry-deposition methods and wet-deposition methods for forming an organic luminescent layer. Using vapor deposition as an example of the dry-deposition methods, which easily forms uniform films, requires patterning with the use of a finely patterned mask, resulting in a difficulty performing fine patterning and obtaining a large substrate.

Recently, the following method has been tried:

a polymer material or a low molecular material is dissolved in a solvent to make a coating fluid, and

a wet-deposition method forms thin films using the coating fluid.

When a wet-deposition method using a coating fluid based on a polymer material or a low molecular material forms a luminescent medium layer containing an organic luminescent layer, the structure of a luminescent medium layer usually has a double layer structure in which a hole transport layer and an organic luminescent layer are stacked in this order from the anode side.

At that time, in order to obtain a color panel, these organic luminescent layers are coated by organic luminescent ink obtained by dissolving or stably dispersing organic luminescent materials having luminescent colors of red (R), green (G), and blue (B) (see patent documents 1 and 2).

In forming organic layers using vapor deposition, large-area fine patterning is difficult, and the cost of the manufacturing facility is high. In contrast, the wet-deposition methods require relatively low cost manufacturing facilities because no vacuum equipment is required, and provide benefits in manufacturing large-area color panels because of use of masks not being required.

As the wet-deposition methods, there are proposed a method of forming patterns using mainly an inkjet system and a method of forming patterns using a printing system. For example, the inkjet system disclosed in patent document 3 injects ink, which has been formed by dissolving a luminescent-layer material in a solvent, onto a substrate from an inkjet nozzle, and dries the ink on the substrate to form a desired pattern.

In the wet-deposition methods, injecting a droplet of an organic-material dissolving solvent into an aperture between partitioning walls and drying the solvent in the opening form an organic-material film. However, it is difficult to uniformly dry a solvent. An uneven solvent during the drying process results in non-uniformity of the thickness of an organic film. Particularly, movement of a solvent through the boundary between a pixel electrode and a partitioning wall results in non-uniformity of a film thickness.

In order to solve these problems, patent document 4 proposes a method of forming a double-layer partitioning wall in order to uniform film thickness. However, this method also results in non-uniformity of the edges of a pixel electrode around the partitioning wall, i.e. an insulating film, resulting in an increase of the manufacturing process.

FIGS. 10, 11A and 11B illustrate examples of the cross section of a sub-pixel in a known organic electro-luminescence display panel. A partitioning wall 202 is formed on the edges of a first electrode 201 of a substrate 202 to cover the edges. An EL light-emitting region 203 of the sub-pixel is defined by the edges of the partitioning wall 202.

In the structure, as illustrated in FIG. 11, during a process of forming an organic layer 204 using a coating method, drying an organic-material dissolving solvent, which has been filled in the aperture, results in non-uniformity of the film thickness due to unevenness of the solvent. Specifically, the closer the portion of the film to the partitioning wall 202 is, the more the film thickness increases, which is illustrated in FIG. 11A such that the center of the film is concaved. As another example opposite thereto, the closer the portion of the film to the partitioning wall 202 is, the more the film thickness decreases, which is illustrated in FIG. 11B such that the center of the film is convexed.

### CITATION LIST

### Patent Document 1

Patent document 1: Japanese Patent Laid-Open No. 2001-93668
Patent document 2: Japanese Patent Laid-Open No. 2001-155858
Patent document 3: Japanese Patent Laid-Open No. H10-12377
Patent document 4: Japanese Patent Laid-Open No. 2010-129419

### SUMMARY OF INVENTION

### Problem to be Solved by Invention

As described above, if the center of an organic film is concaved, the periphery of the EL light-emitting region is relatively high in resistance. This may cause poor light emission from the periphery, resulting in non-uniformity of the emitted light. The non-uniformity of emitted light may impose load only on the high intensity portion, resulting in acceleration of the deterioration of the organic EL element. The non-uniformity of a film thickness may also change the color of emitted light due to optical interference. For example, in a blue element, even if the color of emitted light from the center is blue, the color of emitted light from the periphery may become light blue due to optical interference. On the other hand, the convexed center portion of an organic film causes emitted light from the periphery to increase in intensity, and that from the center to decrease in intensity. This may cause the periphery to become short-circuited, resulting in no light emission.

In order to address such disadvantages, the present invention aims to provide organic electro-luminescence display panels, each of which is designed such that an organic material is formed with a uniform thickness in a light-emitting region, and provide methods of manufacturing these panels.

### Means for Solving Problem

An organic electro-luminescence display panel according to an embodiment of the present invention is provided with a plurality of organic EL elements on a substrate. Each of the plurality of organic EL elements includes a first electrode, a planarizing layer, a partitioning wall, a luminescent medium layer, and a second electrode. The first electrode is formed on the substrate and has an application portion and a connection portion. The planarizing layer is formed around the application portion and has the same thickness as that of the first electrode. The partitioning wall is formed to be separated from edges of the application portion toward the planarizing layer to partition the first electrode. The luminescent medium layer includes at least an organic luminescent layer and is formed, inside of an aperture of the partitioning wall, on the first electrode and the planarizing layer. The second electrode is formed to be separated by the luminescent medium layer from the first electrode.

In this case, the substrate is preferably a thin film transistor substrate. The intervals between the edges of the application portion and the partitioning wall are set within the range from 1 to 30 μm inclusive. The film thickness of the first electrode is set within the range from 5 to 80 nm inclusive. The film thickness of the luminescent medium layer is greater than the film thickness of the first electrode. The luminescent medium layer includes a hole injection layer between the organic luminescent layer and the first electrode. The hole injection layer has a film thickness greater than the film thickness of the first electrode.

A method of manufacturing the organic electro-luminescence display panel according to the one embodiment of the present invention includes the steps of: forming the first electrode and the planarizing layer on the substrate; and forming the luminescent medium layer using a printing method.

In the method, the step of forming the first electrode and the planarizing layer on the substrate includes the steps of: forming a film for the first electrode on the substrate; forming a photoresist film on the film for the first electrode; and exposing and developing the photoresist film to form a photoresist pattern. The step of forming the first electrode and the planarizing layer on the substrate also includes the steps of: forming a pattern of the first electrode by etching; forming a film for the planarizing layer on the photoresist pattern; and eliminating the photoresist pattern to pattern the film of the planarizing layer.

In the method, the step of forming the first electrode and the planarizing layer on the substrate includes the steps of: forming a film for the planarizing layer on the substrate; forming a photoresist film on the film for the planarizing layer; and exposing and developing the photoresist film to form a photoresist pattern. The step of forming the first electrode and the planarizing layer on the substrate also includes the steps of: forming a pattern of the planarizing layer by etching; forming a film for the first electrode on the photoresist pattern; and eliminating the photoresist pattern to pattern the film of the first electrode.

### Effect of the Invention

According to the present invention, it is possible to form, by simple processes, an organic EL display panel provided with organic EL elements including organic layers in which the film thicknesses of the organic layers within their luminescent regions are uniform.

### BRIEF DESCRIPTION OF DRAWINGS

FIG. 1 is a schematic view of an organic EL display panel according to an embodiment of the present invention;

FIG. 2A is a cross sectional view of an example of an organic EL element of the organic EL display panel illustrated in FIG. 1 in which a luminescent medium layer has been just laminated;

FIG. 2B is a cross sectional view of another example of an organic EL element of the organic EL display panel illustrated in FIG. 1 in which a luminescent medium layer has been just laminated;

FIG. 3A is a cross sectional view of the organic EL element illustrated in FIG. 2A on which a second electrode has been formed;

FIG. 3B is a cross sectional view of the organic EL element illustrated in FIG. 2B on which a second electrode has been formed;

FIG. 4 is a plan view illustrating a first electrode and a partitioning wall of the organic EL element illustrated in FIG. 1;

FIG. 5 is a cross sectional view of the organic EL element taken on line F5-F5 in FIG. 4;

FIG. 6 is a schematic view illustrating an example of printing pattern of an organic layer of the organic EL element illustrated in either FIG. 2A or FIG. 2B produced by a relief printing machine;

FIG. 7 is a view illustrating an example of forming the first electrode and a planarizing layer of the organic EL element illustrated in either FIG. 2A or FIG. 2B;

FIG. 8 is a view illustrating another example of forming the first electrode and a planarizing layer of the organic EL element illustrated in either FIG. 2A or FIG. 2B;

FIG. 9 is a schematic view illustrating a normal organic EL display panel;

FIG. 10 is a cross sectional view of a sub-pixel in a normal organic EL display panel;

FIG. 11A is a cross sectional view of an example of a conventional sub-pixel having an organic layer; and

FIG. 11B is a cross sectional view of another example of a conventional sub-pixel having an organic layer.

### DESCRIPTION OF EMBODIMENT

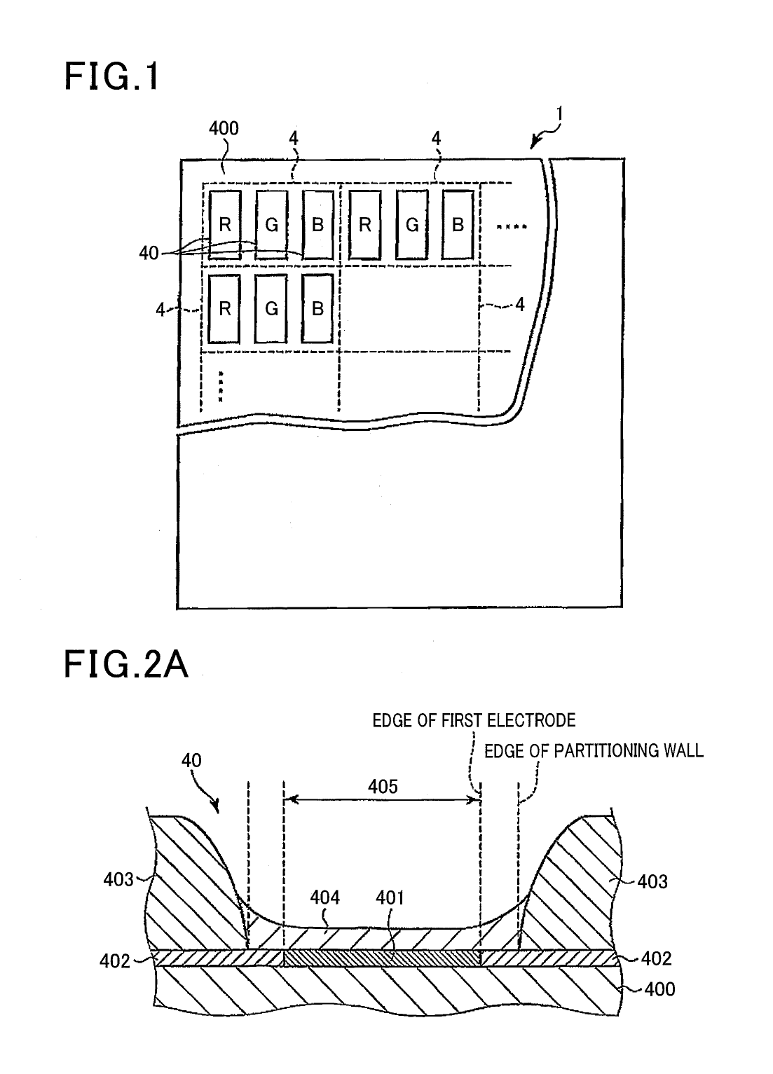

An organic electro-luminescence display panel 1 according to an embodiment of the present invention will be described with reference to FIGS. 1 to 8.

The organic electro-luminescence (EL) display panel 1 illustrated in FIG. 1 is comprised of a plurality of pixels 4 arranged in square array on a substrate 400. Each pixel is comprised of organic EL elements 40 that serve as sub-pixels respectively emitting light of three primary colors of red (R), green (G), and blue (B). The configuration of a sub-pixel and that of another sub-pixel are the same as each other even if the sub-pixels emit light of different colors. For this reason, the configuration of one of the sub-pixels will be described as a representative of them.

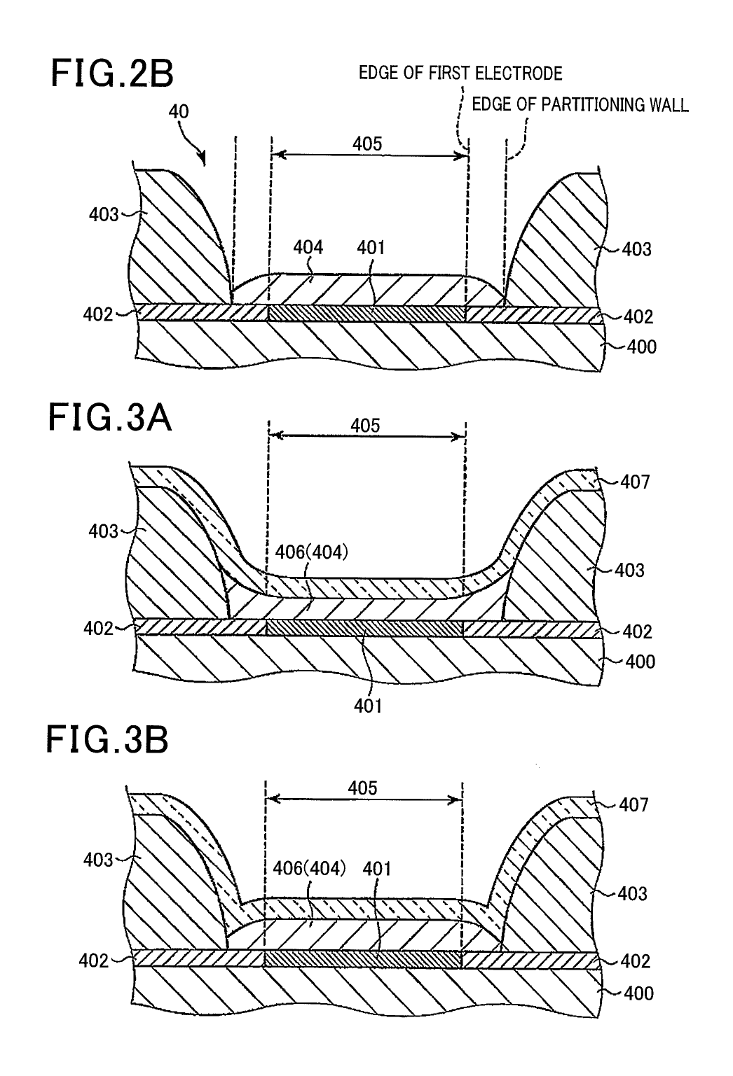

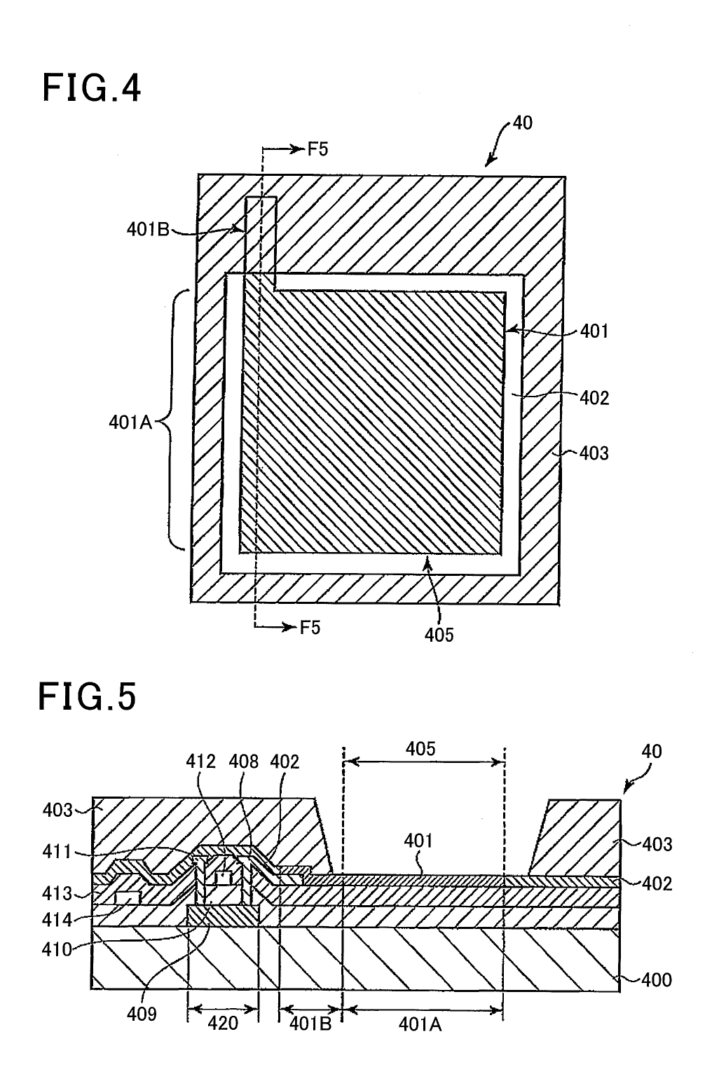

A cross-sectional view of an organic EL element 40 constituting one sub-pixel is illustrated in FIGS. 2A and 2B. In the present invention, an EL light-emitting region 405 is defined by edges, i.e. peripheral ends of a first electrode 401. A partitioning wall 403 is so formed outside of the edges of the first electrode 401 as to uncover the EL light-emitting region 405. As illustrated in FIG. 4, the edges of the first electrode 401 and the corresponding edges of the partitioning wall 403 have substantially uniform intervals therebetween. In FIGS. 2A, 2B, 3A, and 3B, reference numeral 400 represents a substrate, reference numeral 402 represents a planarizing layer, and reference numeral 404 represents an organic luminescent layer contained in a luminescent medium layer 406.

In forming the organic luminescent layer 404 using a coating method, there is a case where the center of the organic luminescent layer 404 surrounded by the edges of the partitioning wall 403 is concaved so that the film has a greater thickness at the portion close to the partitioning wall 403 (see FIG. 2A). Even if there is such a case, the film thickness of a region of the organic luminescent layer 404 located inside the edges of the first electrode 401, i.e. the film thickness of the organic luminescent layer 404 is substantially uniform.

FIG. 2B illustrates a case where the film has a smaller thickness at the portion close to the partitioning wall 403, i.e. the center is convexed. Even if the organic luminescent layer 404 is formed as illustrated in FIG. 2B, the organic EL element 40 according to the present invention is configured such that the edges of the partitioning wall 403 are separated from the corresponding edges of the first electrode 401 toward the side of the planarizing layer 402. This configuration prevents short-circuit faults at the periphery of the EL light-emitting region 405. In view of prevention of short-circuit faults, it is preferable that the organic luminescent layer 404 has a shape that the center is concaved such that the periphery close to the partitioning wall 403 has a greater thickness.

The organic luminescent layer 404 includes at least a luminescent layer. Preferably, the organic luminescent layer 404 is designed as a combination of a plurality of layers on the first electrode 401; the plurality of layers include a hole transport layer, an electron block layer or a hole injection layer, an interlayer, a luminescent layer, an electron injection layer or a hole block layer, and an electron block layer.

FIG. 3A illustrates an example in which a second electrode 407 is formed on the organic EL element 40 illustrated in FIG. 2A. The organic EL element 40 is comprised, in sequence on the substrate 400, of:

the first electrode 401;

the planarizing layer 402 so formed around the first electrode 401 as to have substantially the same film thickness as that of the first electrode 401;

the partitioning wall 403 formed to be separated from the edges of the first electrode 401;

the luminescent medium layer 406 containing at least the organic luminescent layer 404; and

the second electrode 407.

Reference numeral 405 represents the EL light-emitting region.

FIG. 3B illustrates an example in which a second electrode 407 is formed on the organic EL element 40 illustrated in FIG. 2B. Like the case illustrated in FIG. 3A, a part of the luminescent medium layer 406, which includes a part of the organic luminescent layer 404 within the EL light-emitting region 405, has a substantially uniform thickness.

The organic EL element 40 according to the present invention will be further described with reference to the plan view illustrated in FIG. 4. FIG. 4 shows the first electrode 401 and the partitioning wall 403 of the organic EL element 40 constituting a sub-pixel of a pixel 4 of the organic electro-luminescence display panel according to the present invention. The first electrode 401 includes an application portion 401A located in the EL light-emitting region 405, and a connection portion 401B, and is connected to a driver at the connection portion 401B. The planarizing layer 402 is formed around the first electrode 401. The partitioning wall 403 is formed to surround the outer periphery of the application portion 401A of the first electrode 401 at the position spaced away from the edges of the first electrode 401. The connection portion 401B serves as an edge of the EL light-emitting region 405 extending to the partitioning wall 403. Because the region of the connection portion 401B is smaller than the total region, it has a very small impact, and therefore, it can be negligible.

If the intervals between the edges of the application portion 401A of the first electrode 401 and the corresponding edges of the partitioning wall 403 located outside thereof were excessively short, it could be difficult to obtain a uniform film thickness within the EL light-emitting region. If the intervals were excessively large, the light-emitting area could be small. Thus, the intervals between the edges of the application portion 401A of the first electrode 401 and the corresponding edges of the partitioning wall 403 are preferably set within the range from 1 to 30 μm inclusive, and more preferably within the range from 3 to 20 μm inclusive.

FIG. 5 is a cross-sectional view of the organic EL element 40 taken on line F5-F5 in FIG. 4. FIG. 5 shows an example of a top-gate top-contact TFT substrate with a partitioning wall usable in the present invention. The first electrode 401 serving as a pixel electrode is connected to a drain electrode 408 at the connection portion 401B. Reference numeral 401A represents the application portion, reference numeral 409 represents an active layer, reference numeral 410 represents a gate insulator 410, reference numeral 411 represents a source electrode, and reference numeral 412 represents a gate electrode. In addition, reference numeral 413 represents an interlayer insulation layer, reference numeral 402 represents the planarizing layer, reference numeral 403 represents the partitioning wall, and reference numeral 414 represents scanning lines. An insulation film can be covered on a TFT 420 serving as the driver, and, via contact holes formed in the insulation film, the first electrode 401 can be connected to the drain electrode 408.

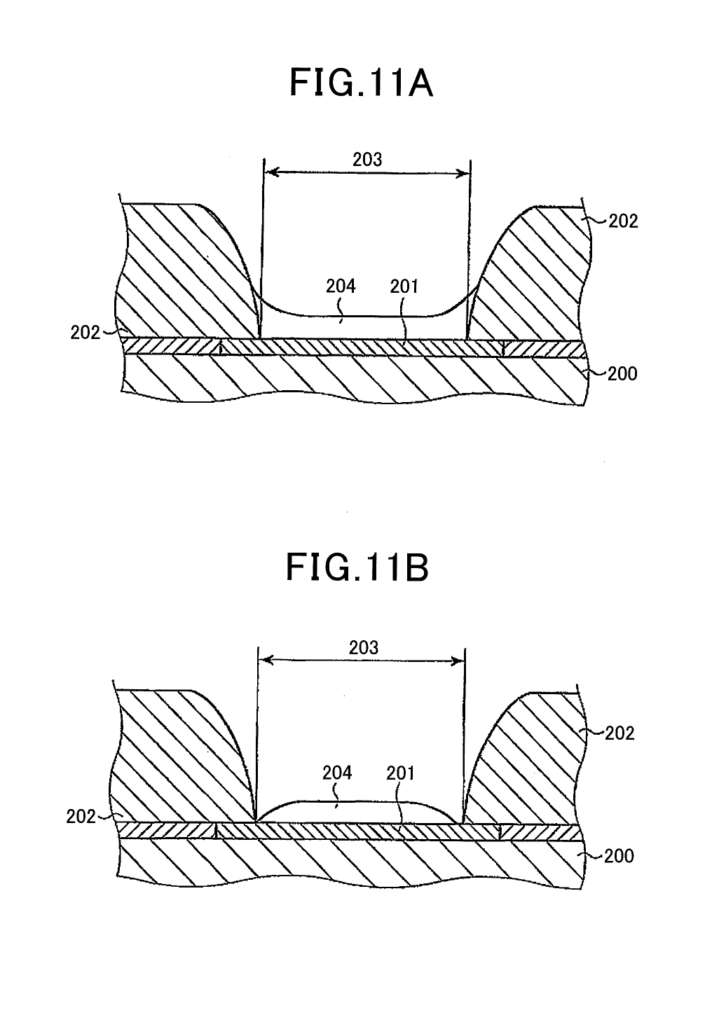

In the known structure illustrated in FIGS. 10, 11A, and 11B, the edges of the partitioning wall 202 are located inside of the corresponding edges of the application portion of the first electrode 201. For this reason, the EL light-emitting region 203 is defined by the aperture of the partitioning wall 202.

In contrast, in the organic EL element 40 having the configuration according to the present invention, as illustrated in FIGS. 2A, 2B, 3A, 3B, 4, and 5, the edges of the partitioning wall 403 are arranged outside of the corresponding edges of the application portion 401A of the first electrode 401. This arrangement substantially defines the EL light-emitting region 405 by the edges of the application portion 401A of the first electrode 401.

As a result of comparison, the edge positions of the application portion 401A of the first electrode 401 and those of the partitioning wall 403 are reversed, and therefore, the EL light-emitting region 405 of the organic EL element 40 is as large as the EL light-emitting region 203 of the organic EL element having the known configuration. Note that the top-gate TFT is illustrated in FIG. 5, but a staggered TFT, an inverted staggered TFT, a bottom-gate TFT, a top-gate TFT, or a coplanar TFT can be used as the TFT configuration according to the present invention.

In the present invention, it is preferable that the film thickness of the first electrode 401 is thin. If the first electrode 401 is thick, there will be a difference in film thickness between the first electrode 401 and the planarizing layer 402, resulting in a leak current likely flowing through the edges of the first electrode 401. Otherwise, if the first electrode 401 is excessively thin, a sheet resistance will be high, which is not preferred because there will be inconsistencies in intensity in the light-emitting surface. Thus, the film thickness of the first electrode 401 is preferably set within the range from 5 to 80 nm inclusive, and more preferably within the range from 20 to 60 nm inclusive.

In view of leak current through the edges of the first electrode 401, it is preferable that the first electrode 401 is thin. However, for passive drive, the first electrode 401 also serves as interconnections, so that, for reduction of interconnection resistance, the film thickness cannot be excessively thin. However, for active drive, it is possible to have a thinner first electrode 401. Thus, it is preferable that the organic electro-luminescence display panel 1 according to the present invention is designed as an active-drive panel, but is not limited thereto.

It is preferable that the film thickness of the planarizing layer 402 is substantially the same as that of the first electrode 401. This is because it is preferable that the luminescent medium layer 406, which contains the organic luminescent layer 404, formed on the first electrode 401 and the planarizing layer 402 is smoothly formed on the boundary of the first electrode 401 and the planarizing layer 402. The difference between the planarizing layer 402 and the first electrode 401 in film thickness is preferably set to be equal to or lower than ±20 nm, and more preferably equal to or lower than ±10 nm.

In order to eliminate leak current through the edges of the first electrode 401, it is preferable that the luminescent medium layer 406 is greater in thickness then the first electrode 401. Particularly, the hole injection layer in the organic luminescent layer 404 contained in the luminescent medium layer 406 is preferably greater in thickness than the first electrode 401.

It is preferable that the luminescent medium layer 406 containing the organic hold injection layer, the interlayer, the organic luminescent layer 404, and the like is formed by a printing method because the luminescent layer 406 covers the edges of the first electrode 401 to reduce leak current. Although the boundary of the first electrode 401 and the planarizing layer 402 is preferably planarized, it actually has stepped portions. The luminescent layer 406 formed by a printing method enables these stepped portions to be eliminated. As an example of the printing method, relief printing, nozzle printing, or spray coating can be preferably used.

Relief printing as an example of the manufacturing method will be described. Particularly, relief printing is suitable for cases where the organic luminescent layers 404 are coated in respective luminescent colors with the use of organic luminescent ink obtained by dissolving or stably dispersing organic luminescent materials. This relief printing can transfer the ink to the inside surrounded by the partitioning wall 403 to perform patterning.

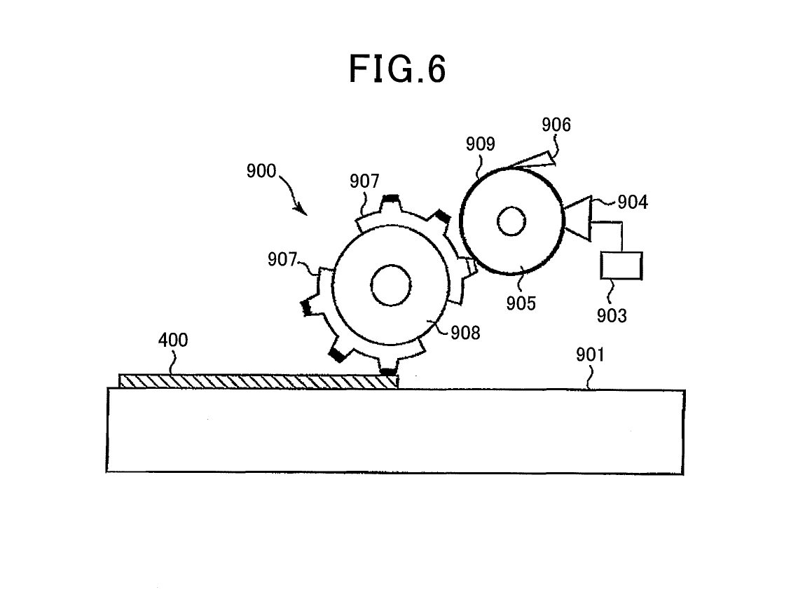

FIG. 6 schematically illustrates a relief printing system 900 that performs pattern printing on the substrate 400 as a print target using organic luminescent ink obtained by dissolving or stably dispersing organic luminescent materials. The manufacturing system is comprised of a stage 901, an ink tank 903, an ink chamber 904, an anilox roll 905, a relief printing plate 907, and a plate cylinder 908 on which the relief printing plate 907 is mounted. The stage 901 holds the substrate 400 as a print target. The ink tank 903 accumulates therein the organic luminescent ink, and feeds the organic luminescent ink supplied from the ink tank 903 into the ink chamber 904. The anilox roll 905 is supported to be rotatable, and is in abutment with an ink supplier of the ink chamber 904. The plate cylinder 908 is arranged adjacent to the anilox roll 905 such that a protrusion of the plate 907 abuts on the surface of the anilox roll 905. Reference numeral 906 represents a doctor.

Rotating the anilox roll 905 causes an ink layer 909 of the organic luminescent ink supplied to the surface of the anilox roll 905 to be formed with a uniform film thickness. The ink of the ink layer 909 is transferred to protrusions of the plate 907 mounted on the plate cylinder 908 arranged adjacent to the anilox roll 905 and rotatably driven thereby. The substrate 400 as a print target is mounted on the stage 901, the ink on the protrusions of the plate 907 is printed thereon. After the ink is subjected to a drying process if necessary, the ink is formed as the organic luminescent layer 404 on the substrate 400 as a print target.

Next, a detailed structure of the present invention will be described,

<Substrate>

As the substrate 400 used in this embodiment of the present invention, a substrate, which can support the organic EL element 40, can be used. For active matrix, a TFT substrate formed with thin film transistors is used. FIG. 5 illustrates an example of the TFT substrate with a partitioning wall usable in the present invention. The TFT 420 and the first electrode 401 serving as a pixel electrode of the organic EL display device are formed on the substrate 400, and the TFT 420 and the first electrode 401 are electrically connected to each other.

TFTs and an active-matrix organic EL display device arranged above them are supported by a supporting member. As the supporting member, any material can be used as long as it has mechanical strength, insulating property, and superior dimension stability. For example, a translucent base, a nontranslucent base, and so on can be used as the material of the supporting member.

The translucent base can be made of: glass, quartz, a plastic film, a plastic sheet, or the stack of a plastic sheet or film and one or more metal-oxide layers, metal fluoride layers, metal nitride layers, metal oxynitride layers, or polymeric resin layers laminated thereon. The plastic film or plastic sheet can be made from polypropylene, polyethersulfone, polycarbonate, cycloolefin polymer, polyarylate, polyamide, polymethyl methacrylate, polyethylene terephthalate, or polyethylene naphthalate. The one or more metal-oxide layers can be made from silicon oxide, aluminum oxide, or the like. The one or more metal fluoride layers can be made from an aluminum fluoride, a magnesium fluoride, or the like. The one or more metal nitride layers can be made from silicon nitride, aluminum nitride, or the like. The one or more metal oxynitride layers can be made from silicon oxynitrides or the like. The one or more polymeric resin layers can be made from acrylic resin, epoxy resin, silicon resin, or polyester resin.

The nontranslucent base can be made of: a metal foil; a metal sheet; a metal plate, whose metals include aluminum, stainless, and the like; or the stack of the plastic sheet or film and a metal film made from aluminum, copper, nickel, stainless, or the like. Whether the supporting member has translucency can be selected depending on which of the surfaces of the substrate from which light is to be transmitted through.

In order to prevent entry of water into the organic EL display device, it is preferable to form inorganic films on a supporting member made from these materials or apply coating of fluorine resin thereto, thus applying moisture-proof property or hydrophobicity to the supporting member made from these materials. Particularly, in order to prevent entry of fluid into the luminescent medium layer 406, it is preferable to select such a supporting member having a low percentage of water content and a low gas-transmission coefficient.

As thin film transistors to be mounted on the supporting member, available thin film transistors can be used. Specifically, thin film transistors each comprised mainly of an active layer in which a source/drain region and a channel region are formed; and a gate insulating layer; and a gate electrode can be used. The thin film transistors can have any configuration. As these thin film transistors, staggered thin film transistors, inverted staggered thin film transistors, top-gate thin film transistors, bottom-gate thin film transistors, or coplanar thin film transistors can be used.

The material of the active layer 409 is not especially limited. The active layer 409 is for example made from an inorganic semiconductor material, such as amorphous silicon, microcrystal silicon, cadmium selenide, or the like, or an organic semiconductor material, such as thiophene oligomer, poly(p-phenylenevinylene), or the like. These active layers can be formed in the following methods including:

a method of laminating amorphous silicon, and performing ion-doping;

a method of forming amorphous silicon by LPCVD using SiH₄ gas, crystallizing the amorphous silicon by solid phase epitaxy to obtain polysilicon, and performing ion-doping by ion implantation;

a method, i.e. a low-temperature process, of forming amorphous silicon by LPCVD using Si₂H₆ gas or PECVD using SiH₄ gas, annealing it using a laser, such as an excimer laser, crystallizing the amorphous silicon to obtain polysilicon, and performing ion-doping by an ion-doping method; and a method, i.e. a high-temperature process, of laminating polysilicon by low-pressure CVD or LPCVD, forming a gate insulating layer by thermal oxidation at 1000° C. or over, forming a gate electrode made from n+ polysilicon, and performing ion-doping by the ion-doping method.

The gate insulating layer 410 illustrated in FIG. 5 can be made from a material, which is usually used as gate insulating layers, such as SiO₂ formed by PECVD or PECVD, SiO₂ obtained by thermal oxidation of a polysilicon film, or the like.

The gate electrode 412 illustrated in FIG. 5 can be made from metal, such as aluminum, copper, or the like; high-melting-point metal, such as titanium, tantalum, tungsten, or the like; polysilicon; refractory metal silicide; polycide; or the like.

The thin film transistors can have a single-gate structure, a double-gate structure, or multi-gate structure with three or more gate electrodes. The thin film transistors can also have a LDD structure or an offset structure. Two or more thin film transistors can be placed in a single pixel.

In the display device according to the present invention, connections of thin film transistors are required to serve the thin film transistors as switching elements for the organic EL display device, and therefore, the drain electrode 408 of a transistor is electrically connected to a pixel electrode of the organic EL display device.

<Pixel Electrode>

A film of the first electrode 401 serving as a pixel electrode is formed on the substrate 400, and patterning is carried out if necessary. As a material of pixel electrodes, a metal composite oxide, such as an ITO (Indium Tin composite Oxide), an indium zinc composite oxide, a zinc aluminum composite oxide, or the like; a metal material, such as gold, platinum, or the like; or fine-grained film formed by dispersing fine grains of these metal oxides or metal materials can be used in the form of a single layer or multiple layers. If a pixel electrode serves as a cathode, a material having a high work function, such as ITO, is preferably selected. For a bottom-emission structure in which light is taken out from the bottom, a material having translucency need be selected. As a method of forming pixel electrodes, a dry film-forming process, a wet film-forming process, or the like can be used depending on the material. Dry film-forming processes include heat resistance evaporation, electron beam evaporation, reactive evaporation, ion plating, sputtering, and the like. Wet film-forming processes include gravure printing, screen printing, and the like. As a method of patterning pixel electrodes, one of the available patterning methods, such as mask vapor deposition, photolithography, wet etching, dry etching, and the like, can be used depending on the material and the film forming process. In the present invention, photolithography is preferably used.

<Planarizing Layer>

The planarizing layer 402 according to the present invention is formed around the first electrode 401. As a material of the planarizing layer 402, an insulating inorganic material is preferably used. Insulating inorganic materials include a silicon nitride, a silicon oxide, alumina, and the like. As a method of forming the planarizing layer 402, a dry film-forming process, a wet film-forming process, or the like can be used depending on the material. Dry film-forming processes include heat resistance evaporation, electron beam evaporation, reactive evaporation, ion plating, sputtering, and the like. Wet film-forming processes include gravure printing, screen printing, and the like. As a method of patterning the planarizing layer 402, pixel electrodes, one of the available patterning methods, such as mask vapor deposition, photolithography, wet etching, dry etching, and the like, can be used depending on the material and the film forming process. In the present invention, photolithography is preferably used.

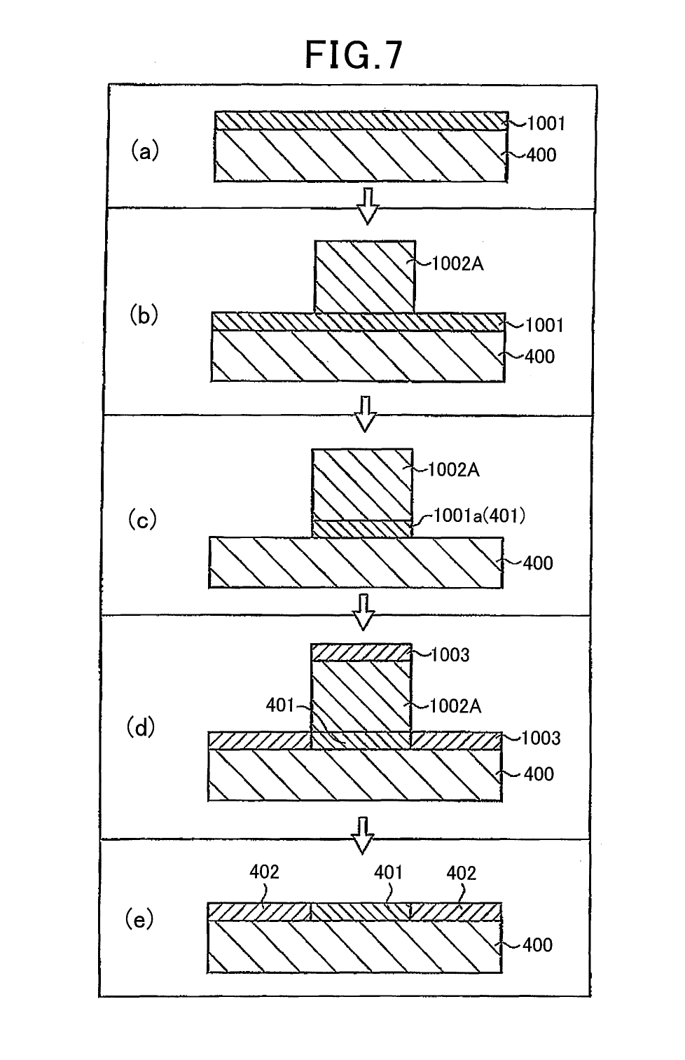

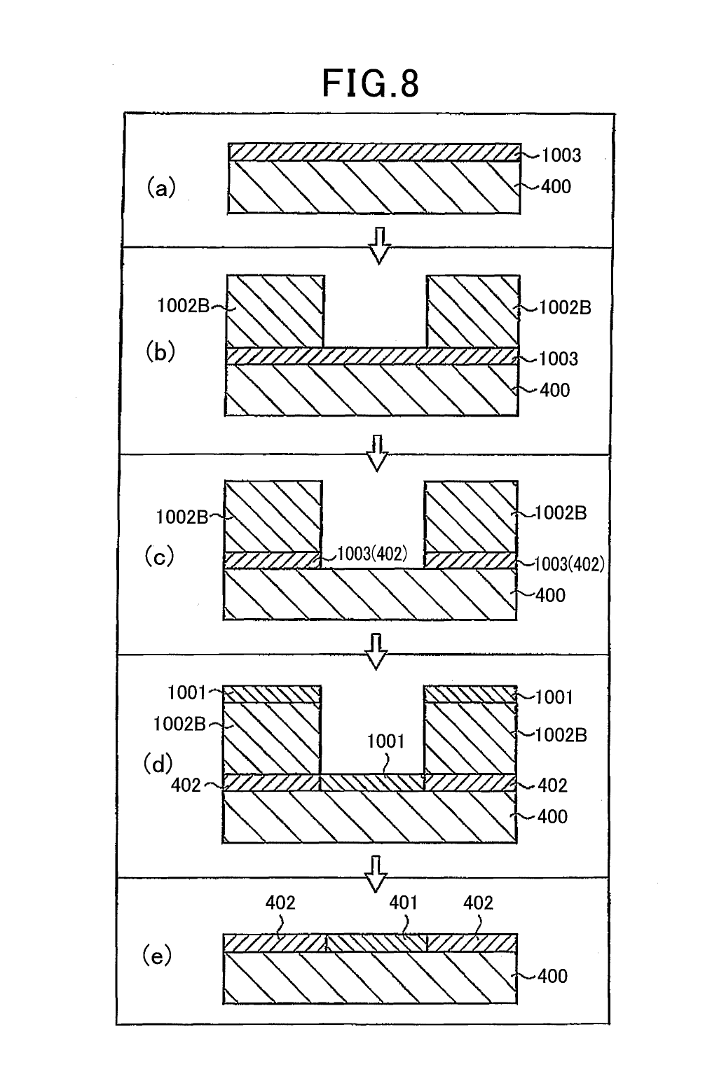

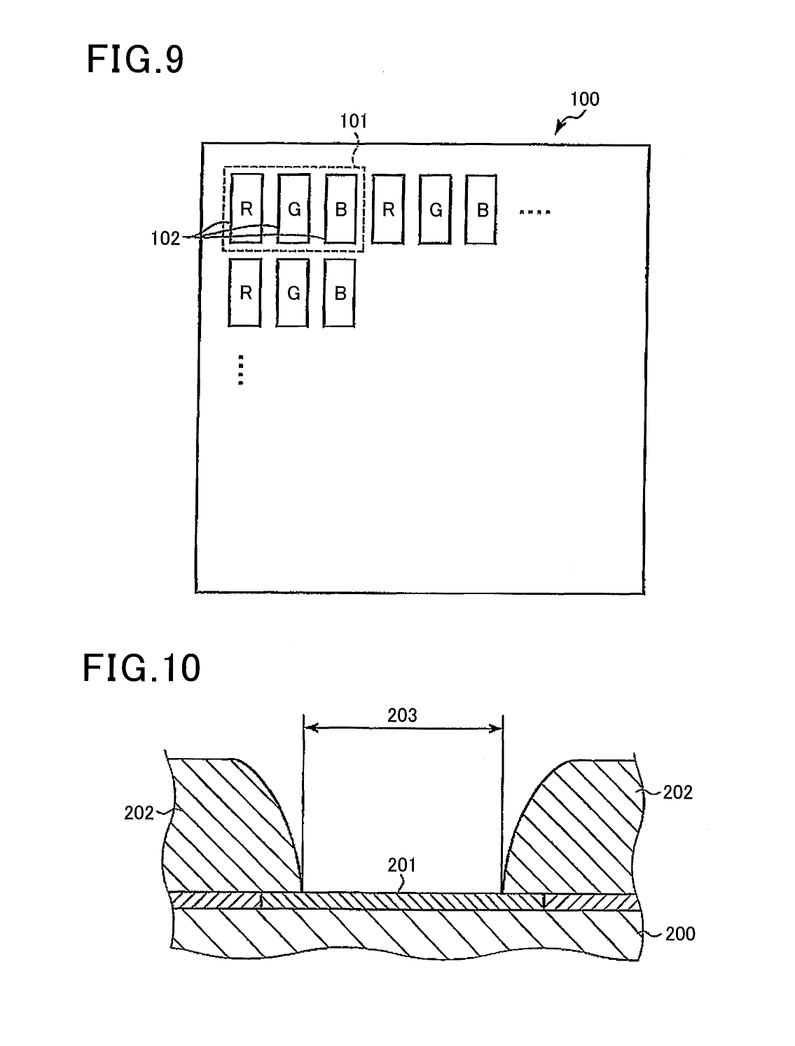

Because it is necessary that the first electrode 401 and the planarizing layer 402 are formed without being separated from each other, it is preferable that they are formed in the processes illustrated in FIG. 7 or FIG. 8.

An example of the processes for forming and patterning the first electrode 401 and the planarizing layer 402 is illustrated in FIG. 7.

Referring to (a) of FIG. 7, a film 1001 for the first electrode 401 is formed on the substrate 400. Coating of a photoresist is applied on the formed film 1001 for the first electrode 401. The photoresist is exposed using a photomask having a pattern, and thereafter is developed, so that a photoresist pattern 1002A is formed as illustrated in (b) of FIG. 7. Etching a part of the film 1001 for the first electrode 401 on which no photoresist pattern 1002A is farmed obtains a pattern 1001a of the first electrode 401 as illustrated in (c) of FIG. 7. Thereafter, as illustrated in (d) of FIG. 7, a film 1003 for the planarizing layer 402 is formed on the photoresist pattern 1002A and the substrate 400. Eliminating the layer of the photoresist pattern 1002A from the first electrode 401 simultaneously eliminates the film 1003 for the planarizing layer 402 formed on the photoresist pattern 1002A, so that the planarizing layer 402 is patterned on the substrate 400 (see (e) of FIG. 7).

Another example of the processes for forming and patterning the first electrode 401 and the planarizing layer 402 is illustrated in FIG. 8.

Referring to (a) of FIG. 8, a film 1003 for the planarizing layer 402 is formed on the substrate 400. Coating of a photoresist is applied on the formed film 1003 for the planarizing layer 402. The photoresist is exposed using a photomask having a pattern, and thereafter is developed, so that a photoresist pattern 1002B is formed as illustrated in (b) of FIG. 8. Etching a part of the film 1003 for the planarizing layer 402 on which no photoresist pattern 1002B is formed obtains a pattern of the planarizing layer 402 as illustrated in (c) of FIG. 8. Thereafter, as illustrated in (d) of FIG. 8, a film 1001 for the first electrode 401 is formed on the photoresist pattern 1002B and the substrate 400. Eliminating the layer of the photoresist pattern 1002B simultaneously eliminates the film 1001 for the first electrode 401 formed on the photoresist pattern 1002B, so that the first electrode 401 is patterned (see (e) of FIG. 8).

<Partitioning Wall>

The partitioning wall 403 according to the present invention is formed around the outside of the EL light-emitting region 405 corresponding to a pixel and around the outside of the first electrode 401. If the organic luminescent layer 404 is formed using a coating method, the partitioning wall 403 is formed to provide an aperture in which an organic-material dissolving solvent is to be filled.

Methods of forming the partitioning wall 403 include:

a method of uniformly forming an inorganic film on a base, masking it using a resist, and performing dry-etching; and

a method of laminating a light-sensitive resin, and forming a predetermined pattern using photolithography.

The height of the partitioning wall 403 is preferably set to be within the range from 0.1 to 10 μm inclusive, and more preferably within the range from 0.5 to 2 μm inclusive. This is because: an excessively greater height would interrupt formation and sealing of an opposite electrode, and an excessively lower height would cause, when forming the luminescent medium layer 406, color mixture between an adjacent pixel and ink. As a lyophilic partitioning wall, light-sensitive resin can be suitably used. As the light-sensitive resin, either a positive resist or negative resist can be used. Specifically, polyimide light-sensitive resin, acrylic light-sensitive resin, or novolak resin can be used as the light-sensitive resin. If necessary, after the partitioning wall 403 is formed by plasma or UV exposure, it is possible to give it lyophilic property to ink.

<Organic EL Element>

As an example, the organic EL element 40 is configured such that, on the first electrode 401, a hole injection layer, an interlayer, the organic luminescent layer 404, and an electron transport layer are mounted as the luminescent medium layer 406 in sequence, and the second electrode 407 is formed. A part of the layers laminated between the electrodes can be eliminated, and other layers, such as a hole block layer and so on can be added to the layers laminated between the electrodes. The layers to be stacked as the luminescent layer 406 are arbitrarily selected from known layers.

<Hole Injection Layer>

The hole injection layer has a function that the injection of holes from the first electrode 401 takes place. The hole injection layer has a work function equal to or higher than the work function of the corresponding pixel electrode because of efficiently injecting holes from the pixel electrode to the interlayer. It can be set within the range from 4.5 to 6.5 eV inclusive, which depends on the material of the pixel electrode, and if the pixel electrode is ITO or IZO, it can be set within the range from 5.0 to 6.0 eV inclusive. The resistivity of the hole injection layer is preferably set to be within the range from 1×10³ to 2×10⁶ Ωm inclusive if the film thickness is equal to or greater than 30 nm, and more preferably, within the range from 5×10³ to 1×10⁶ Ωm inclusive. For the bottom-emission structure, because emitted light is output from the pixel-electrode side, the light extraction efficiency may be reduced if the optical transparency is low. For this reason, the overall average of the optical transparency in the visible-wavelength region is preferably set to be equal to or higher than 75%, and more suitably equal to or higher than 85%.

As a material of the hole injection layer, a polymer material, such as polyaniline, polythiophene, polyvinyl carbazole, the mixture of poly(3, 4-ethylenedioxythiophene) and polystyrene sulfonate, or the like can be used, and, in addition, a conductive polymer with the conductivity set to be within the range from 10⁻²S/cm to 10⁻²S/cm inclusive can be preferably used. Polymer materials can be used during a wet film-forming process. For this reason, a polymer material is preferably used to form the hole injection layer. Such a polymer material is dispersed or dissolved in water or a solvent, and can be used as a dispersion liquid or a solution.

If an inorganic material is used as a hole-transport material, Cu₂O, Cr₂O₃, Mn₂O₃, FeOx (x˜0.1), NiO, CoO, Bi₂O₃, SnO₂, ThO₂, Nb₂O₅, Pr₂O₃, Ag₂O, MoO₂, ZnO, TIO₂, V₂O₅, Nb₂O₅, Ta₂O₅, MoO₃, WO₃, MnO₂, or the like can be used.

As an example, the hole injection layer can be formed on the total area of the display region of the pixel electrode using a simple method, such as spin coating, die coating, dip coating, spray coating, or the like. It is also possible to use a wet film-forming process as an example of the known film-forming processes, such as relief printing, gravure printing, screen printing, or the like. In forming the hole transport layer, ink, i.e. a liquid material, which is formed by dissolving the hole transport material in water, an organic solvent, or a combined solvent of them, is used. As the organic solvent, toluene, xylene, anisole, mesitylene, tetralin, acetone, methyl ethyl ketone, methyl isobutyl ketone, cyclohexanone, methanol, ethanol, isopropyl alcohol, ethyl acetate, butyl acetate, or the like can be used. To the ink, a surface-active agent, an antioxidizing agent, a viscosity modifier, an ultraviolet absorber, or the like can be added. If the hole transport layer is made from an inorganic material, it is possible to form the hole injection layer using a dry process, such as heat resistance evaporation, electron beam evaporation, reactive evaporation, ion plating, sputtering, and the like.

<Interlayer>

The interlayer is laminated between the organic luminescent layer 404 and the hole injection layer, and operative to improve the emission lifetime of the element.

Organic materials of the interlayer include polyvinyl carbazole or its derivatives, polyarylene derivatives having aromatic amine in the main chain or a side chain, arylamine derivatives, polymers containing aromatic amine, such as triphenylamine, and the like. Inorganic materials include transition metal oxides, such as Cu₂O, Cr₂O₃, Mn₂O₃, NiO, CoO, Pr₂O₃, Ag₂O, MoO₂, ZnO, TIO₂, V₂O₅, Nb₂O₅, Ta₂O₅, MoO₃, WO₃, MnO₂, or the like, their nitrides, and inorganic compounds containing one or more sulfides. However, the present invention is not limited to them.

These organic materials are dissolved or stably dispersed in a solvent to become ink for an organic interlayer. As a solvent in which the organic interlayer material is to be dissolved or dispersed, toluene, xylene, anisole, mesitylene, tetralin, acetone, methyl ethyl ketone, methyl isobutyl ketone, cyclohexanone, or mixed solvents of them can be used. Particularly, aromatic organic solvents, such as toluene, xylene, and anisole, are preferably used in view of the resolvability of the organic interlayer material. To the organic interlayer ink, a surface-active agent, an antioxidizing agent, a viscosity modifier, an ultraviolet absorber, or the like can be added if need arises.

As the interlayer material, it is preferable to select a material having a work function equal to or higher than the work function of the hole injection layer, and more preferably, a material having a work function equal to or lower than the work function of the luminescent layer. This aims to prevent unnecessary injection barriers from being formed when carriers are injected from the hole injection layer to the luminescent layer. In order to achieve an effect of confining charges, which do not contribute to the light emission from the luminescent layer, the bandgap is preferably set to be equal to or higher than 3.0 eV, more preferably, equal to or higher than 3.5 eV.

As a method of forming the interlayer, it is possible to use a wet film-forming process as an example of the known film-forming processes, such as relief printing, gravure printing, screen printing, or the like depending on the material.

<Organic Luminescent Layer>

After the interlayer is formed, the organic luminescent layer 404 is formed. The organic luminescent layer 404 is a layer that emits light when current passes therethrough. If display light emitted from the light emitting layer 404 is monochromatic light, the organic luminescent layer 404 is formed to cover the interlayer. However, in order to obtain multicolored light, the organic luminescent layer 404 is subjected to patterning if necessary, and thereafter is used suitably.

As an organic luminescent material forming the organic luminescent layer 404, a material formed by dispersing a luminescent dye in a polymer or a polymer material, such as a polyarylene polymer material, a polyarylene-vinylene polymer material, or a polyfluorene polymer material, can be used. As the luminescent dye, a coumarin dye, a perylene dye, a pyran dye, an anthrone dye, a porphyrin dye, a quinacridone dye, an N,N′-dialkyl substituted quinacridone dye, a naphthalimide dye, an N,N′-diaryl substituted pyrrolo-pyrrole dye, an iridium complex dye or the like can be used. The present invention is however not limited to these materials.

These organic luminescent materials are dissolved or stably dispersed in a solvent to become organic luminescent ink. As a solvent in which the organic luminescent material is to be dissolved or dispersed, toluene, xylene, anisole, mesitylene, tetralin, acetone, methyl ethyl ketone, methyl isobutyl ketone, cyclohexanone, or mixed solvents of them can be used. Particularly, aromatic organic solvents, such as toluene, xylene, and anisole, are preferably used in view of the resolvability of the organic luminescent material. To the organic luminescent ink, a surface-active agent, an antioxidizing agent, a viscosity modifier, an ultraviolet absorber, or the like can be added if need arises.

In addition to the aforementioned polymer materials, it is possible to use low molecular materials including: 9,10-diaryl anthracene derivatives, pyrene, coronene, perylene, rubrene, 1, 1, 4, 4-Tetraphenyl butadiene, tris(8-quinolato) aluminum complex, tris(4-methyl-8-quinolato) aluminum complex, bis(8-quinolato) zinc complex, tris(4-methyl-5-trifluoromethyl-8-quinolato) aluminum complex, tris(4-methyl-5-cyano-8-quinolato) aluminum complex, bis(2-methyl-5-trifluoromethyl-8-quinolinolato) [4-(4-cyanophenyl) phenolate] aluminum compound, tris(8-quinolato) scandium complex, bis[8-(PARA tosyl)aminoquinoline] zinc complex and cadmium complex, 1,2,3,4-tetraphenylcyclopentadienone, poly-2,5-diheptyl-para-phenylenevinylene, and the like.

As a method of forming the organic luminescent layer, it is possible to use a wet film-forming process as an example of the known film-forming processes, such as relief printing, gravure printing, screen printing, or the like.

<Electron Injection Layer>

After the organic luminescent layer 404, it is possible to form the hole block layer or the electron injection layer. These function layers can be arbitrarily selected depending on the size and the like of the organic EL display panel 1. For the hole block layer and the electron injection layer, materials used as electron-transport materials can be used. Using a low molecular material, such as triazole series, oxazole series, oxadiazole series, silole series, boron series, or the like; an alkali metal salt, such as a lithium fluoride; an alkaline-earth metal salt; an alkali metal oxide, such as lithium oxide; or an alkaline-earth-metal oxide permits film formation based on vacuum deposition. These electron-transport materials are dissolved in a polymer, such as polystyrene, polymethyl methacrylate, polyvinyl carbazole, or the like, and thereafter, it is dissolved or dispersed in toluene, xylene, anisole, mesitylene, tetralin, acetone, methyl ethyl ketone, methyl isobutyl ketone, cyclohexanone, or mixed solvents of them, obtaining an electron-injection application liquid. The electron-injection application liquid permits film formation using a printing method.

<Opposite Electrode>

Next, the opposite electrode, i.e. the second electrode 407 is formed. If the opposite electrode is used as an anode, a material having a high electron-injection efficiency with respect to the organic luminescent layer 404 and a low work function is used. Specifically, a metal, such as Mg, AL, Yb, or the like, is used alone; with a compound, such as Li, Li oxide, LiF, or the like being filled in the interface with respect to the luminescent medium layer 406 by the order of 1 mm; or with Al or Cu, having a high stability and conductivity, being laminated. In order to achieve a balance between the electron-injection efficiency and the stability, one or more metals having a low work function, such as Li, Mg, Ca, Sr, La, Ce, Er, Eu, Sc, Y, Yb, and so on, and a stable metallic element, such as Ag, AL, Cu, or the like can be used in combination. Specifically, an alloy, such as MgAg, AlLi, CuLi, or the like can be used.

As a method of forming the opposite electrode, it is possible to use heat resistance evaporation, electron beam evaporation, reactive evaporation, ion plating, or sputtering depending on the material.

<Passivation Layer>

It is possible to form a passivation layer on the opposite electrode for protection of the organic EL element 40 against oxygen or fluids from the outside. As the passivation layer, a metal oxide, such as a silicon oxide, or an aluminum oxide; a metal fluoride, such as aluminum fluoride, a magnesium fluoride, or the like; a metal nitride, such as a silicon nitride, aluminum nitride, a carbon nitride, or the like; a metal oxynitride, such as a silicon oxynitride or the like; a metal carbide, such as a silicon carbide; or the like can be used. If need arises, the stack of such a material and a polymer resin film, such as an acrylic-resin film, an epoxy-resin film, a silicon-resin film, a polyester-resin film, or the like can be used. Particularly, a silicon oxide, a silicon oxynitride, or a silicon nitride is preferably used in view of barrier performance and transparency. Using a film stack or a gradient film with its variable density permits step coverage property and barrier performance to be balanced.

As a method of forming the passivation layer, heat resistance evaporation, electron beam evaporation, reactive evaporation, ion plating, sputtering, or CVD can be used depending on the material. In view of step coverage suitability and barrier performance and because of easy variations of the film density and film composition depending on the film formation conditions, CVD is preferably used. As CVD, heat CVD, plasma CVD, catalytic CVD, VUV-CVD, or the like can be used. As reactant gas used for CVD, an organic silicon compound, such as monosilane, hexamethyldisilazane (HMDS), or tetraethoxysilane, into which gas, such as N₂, O₂, NH₃, H₂, N₂O, or the like, has been added if necessary, can be used. If need arises, it is possible to change the flow of gas, such as silane, and/or plasma power, thus changing the film density. Hydrogen or carbon can be contained in the film depending on reactant gas to be used. The film thickness of the passivation layer is set to be equal to or lower than 5 μm, more preferably than 1 μm.

<Sealing Member>

Organic EL display devices include a luminescent material between electrodes, and emit light when current is applied thereto. However, organic luminescent materials may be easily deteriorated under moisture or oxygen in the atmosphere. For this reason, sealing members are usually provided to block the outside. A sealing member for example has a structure that a resin layer is mounted on a sealing material.

A sealing material must be a base having a low oxygen permeability and a low moisture permeability. As an example of the material, ceramics, such as alumina, silicon nitride, boron nitride, or the like, glass, such as alkali-free glass, alkali glass, or the like, quartz, a moisture-resistant film, or the like can be used. Moisture-resistant films include, as their examples, a film constructed by forming SiOx on both sides of a plastic substrate by CVD; and a polymer film constructed by applying a film having water-absorbability on a film having a low permeability or applying coating of a water absorption agent thereon. It is preferable that these moisture-resistant films have a moisture vapor transmission rate set to be equal to or lower than 10⁻⁶ g/m²/day.

Materials usable for the resin layer include: photo-curing adhesive resin made from epoxy resin, acrylic resin, silicon resin, or the like; thermosetting adhesive resin; two-part curing adhesive resin; acrylic resin, such as ethylene-ethyl-acrylate (EEA) polymer; vinyl resin, such as ethylene-vinyl-acetate (EVA); thermoplastic resin, such as polyamide, synthetic rubber, or the like; and thermoplastic adhesive resin, such as an acid-modified material of polyethylene or polypropylene. As an example of the method of forming the resin layer on the sealing material, a solvent solution method, an extrusion laminating method, a melting and hot melting method, a calendaring method, a nozzle coating method, screen printing, vacuum laminating, heat-roll laminating, or the like can be used. If need arises, a sealing material in which a material having a moisture or oxygen absorption characteristic has been contained can be used. The thickness of the resin layer formed on the sealing material is arbitrarily determined depending on the size and shape of the organic EL display device to be sealed, and, preferably, deter mined to be within the range from 5 to 500 μm inclusive. Note that the resin layer is formed on the sealing material, but it can be directly formed on the organic EL display device.

Finally, lamination of the sealing member and the organic EL display device is performed in a sealing room. The sealing member has a double layer structure of the sealing material and the resin layer. If thermoplastic adhesive resin is used as the resin layer, it is preferable to only perform pressure bonding using a heated roll. If thermosetting adhesive resin is used as the resin layer, it is preferable to perform pressure bonding using a heated roll, and thereafter perform thermal curing at a curing temperature. If photo-curing adhesive resin is used as the resin layer, it is possible to perform pressure bonding using a roll, and thereafter irradiate light to perform curing.

### EXAMPLES

### First Example

Examples of the present invention will be described hereinafter.

As the substrate 400, an active-matrix substrate equipped with thin film transistors (TFTs) and pixel electrodes formed above the respective thin film transistors was used. The thin film transistors are provided on a supporting member and serve as switching elements. The size of the substrate is 200 mm×200 mm. A 5-inch diagonal display having 320×240 pixels is located at the center of the substrate.

An ITO was used as a pixel electrode. An ITO film was formed on the substrate by sputtering. The film thickness is set to be 40 nm. A photoresist was formed on the ITO film. The photoresist was exposed using a photomask having formed with a pattern, and thereafter was developed, so that a photoresist pattern was formed. Etching a part of the ITO film on which no photoresist pattern was formed obtained a pattern of the ITO.

SiO₂, which was going to the planarizing layer 402, was formed on the photoresist pattern by sputtering. The film thickness is set to be 40 nm. Elimination of the photoresist pattern simultaneously eliminated the SiO₂ film, so that the SiO₂ film was patterned.

The ITO pattern has the connection portion 401B, and is connected to the TFT 420 via the connection portion 401B. Thereafter, the partitioning wall 403 having lyophilic property was formed. As the partitioning wall 403, a film having a thickness of 2 μm was formed over an entire surface of the substrate by a spin coater method using a positive resist, and thereafter, patterning was performed using photolithography, so that the partitioning wall 403 was formed. The edges of the partitioning wall were formed outside of the corresponding edges of the ITO, i.e. EL luminescent portion by 3 μm.

After the partitioning wall was formed, as the hole injection layer, the mixture of poly(3,4-ethylenedioxythiophene) and polystyrene sulfonate was formed with the film thickness of 60 nm by relief printing.

The substrate, after the hole injection layer was formed, was set to a printing machine. Then, the interlayer was printed on the hole injection layer by relief printing using ink; the ink had been obtained by dissolving a polyvinyl carbazole derivative as a material of the interlayer in toluene such that the concentration of the polyvinyl carbazole derivative became 0.5%. At that time, an anilox roll having 300 lines per inch and a photopolymer printing plate were used. After dried, the film thickness of the interlayer became 20 nm.

The substrate, after the interlayer was formed, was set to a printing machine. Then, the organic luminescent layer 404 was printed on the interlayer by relief printing using ink; the ink had been obtained by dissolving a polyphenylene vinylene derivative as an organic luminescent material in toluene such that the concentration of the polyphenylene vinylene derivative became 1%. At that time, an anilox roll having 150 lines per inch and a photopolymer printing plate matching pitches of pixels were used. After the organic luminescent ink was dried, the film thickness of the organic luminescent layer 404 became 80 nm.

These processes were repeated at three times, so that the organic luminescent layers 404 corresponding to respective luminescent colors of red (R), green (G), and blue (B) were formed for each pixel 4.

After the organic luminescent layers for all the luminescent colors were formed, as the second electrode, a film of barium was fog med with 4 nm, and a film of aluminum was formed on the barium film with 150 nm.

After the second electrode was formed, a glass plate as a sealing member was mounted to cover all the luminescent regions, and an adhesive was thermally cured at approximately 90° C. for one hour, so that sealing was completed.

As a result of driving the active-matrix organic EL display device obtained in the aforementioned procedure, it could be possible that the active-matrix organic EL display device was successfully driven. As a result of measurement of the luminescent medium layer 406 with a step gauge, the film thickness of a portion of the luminescent medium layer 406 close to the partitioning wall was thicker, but a portion of the luminescent medium layer 406 within the EL luminescent range 405 was substantially flat. From the EL luminescent regions 405 of the sub-pixels constructed by the organic EL elements 40, uniform light-emissions were obtained.

As a result of measuring the intensity of the panel constructed by the organic EL elements 40 according to the first example while the panel emits blue light, in the characteristics of the sub-pixels emitting blue light, the efficiency was 4.7 cd/A, and the chromaticity was (0.14, 0.18).

### First Comparison Example

An active-matrix organic EL display device was manufactured as a first comparison example in the same processes as those of the first example except that the partitioning wall was formed to cover the edges of the ITO used as the first electrode.

As a result of driving the active-matrix organic EL display device according to the first comparison example obtained in the aforementioned procedure, the center portion of a sub-pixel emitted light, but the peripheral portion of the sub-pixel did not emit light. As a result of measurement of the luminescent medium layer of a sub-pixel with a step gauge, the center portion was concaved relative to the peripheral portion, so that the sub-pixel did not emit light because the film thickness of the peripheral portion was thicker.

As a result of measuring the intensity of the panel constructed by the organic EL elements 40 according to the first example while the panel emits blue light, in the characteristics of the sub-pixels emitting blue light, the efficiency was 4.1 cd/A, and the chromaticity was (0.14, 0.21). Because the film thicknesses of the luminescent medium layers were non-uniform in the comparison example, the chromatic purity was deteriorated as compared with that of the first example.

### DESCRIPTION OF CHARACTERS

1 Organic electro-luminescence (EL) display panel
4 Pixel
40 Organic EL element
400 Substrate
401 First electrode
401A Application portion
401B Connection portion
402 Planarizing layer
403 Partitioning wall
404 Organic luminescent layer
405 EL luminescent region
406 Luminescent medium layer
407 Second electrode
1001 Film (of first electrode)
1001a Pattern (of first electrode)
1002A, 1002b Photoresist pattern
1003 Film (of planarizing layer)

1. An organic electro-luminescence display panel comprising:
a substrate; and
at least one organic electro-luminescence element formed on the substrate,
the at least one organic electro-luminescence element comprising:
a first electrode formed on the substrate and having an electrode portion and a connection portion for drive of the first electrode;
a planarizing layer formed around edges of the electrode portion, the planarizing layer being configured to planarize a boundary with the first electrode;
a partitioning wall having an aperture at an inside thereof, the partitioning wall being formed to be separated from the edges of the electrode portion toward the planarizing layer;
a luminescent medium layer including at least an organic luminescent layer and formed, in the aperture of the partitioning wall, on the first electrode and the planarizing layer; and
a second electrode formed to be separated by the luminescent medium layer from the first electrode.

2. The organic electro-luminescence display panel according to claim 1, wherein the substrate is a thin film transistor substrate.

3. The organic electro-luminescence display panel according to claim 1, wherein intervals between the edges of the application portion and the partitioning wall are set within a range from 1 to 30 μm inclusive.

4. The organic electro-luminescence display panel according to claim 1, wherein a film thickness of the first electrode is set within a range from 5 to 80 nμm inclusive.

5. The organic electro-luminescence display panel according to claim 1, wherein a film thickness of the luminescent medium layer is greater than a film thickness of the first electrode.

6. The organic electro-luminescence display panel according to claim 1, wherein the luminescent medium layer comprises a hole injection layer between the organic luminescent layer and the first electrode, the hole injection layer having a film thickness greater than a film thickness of the first electrode.

7. A method of manufacturing the organic electro-luminescence display panel according to claim 1, the method comprising the steps of:
forming the first electrode and the planarizing layer on the substrate; and
forming the luminescent medium layer using a printing method.

8. The method of manufacturing the organic electro-luminescence display panel according to claim 7, wherein the step of forming the first electrode and the planarizing layer on the substrate comprises the steps of:
forming a film for the first electrode on the substrate;
forming a photoresist film on the film for the first electrode;
exposing and developing the photoresist film to form a photoresist pattern;
forming a pattern of the first electrode by etching;
forming a film for the planarizing layer on the photoresist pattern; and
eliminating the photoresist pattern to pattern the film of the planarizing layer.

9. The method of manufacturing the organic electro-luminescence display panel according to claim 7, wherein the step of forming the first electrode and the planarizing layer on the substrate comprises the steps of:
forming a film for the planarizing layer on the substrate;
forming a photoresist film on the film for the planarizing layer;
exposing and developing the photoresist film to form a photoresist pattern;
forming a pattern of the planarizing layer by etching;
forming a film for the first electrode on the photoresist pattern; and
eliminating the photoresist pattern to pattern the film of the first electrode.
